(19) United States
(12) Patent Application Publication
(10) Pub. No.: US 2014/0290917 A1
(43) Pub. Date: Oct. 2, 2014

(54) HEAT DISSIPATING PAD

(71) Applicant: COOLER MASTER CO., LTD., New Taipei City (TW)

(72) Inventors: Shih-Yi Chang, New Taipei City (TW); Ying-Chun Chen, New Taipei City (TW); Yuan-Chin Chen, New Taipei City (TW); XIAOBIN YAN, New Taipei City (TW); Yi-Hsuan Huang, New Taipei City (TW); Ben-Tien Lin, New Taipei City (TW); Ching-Feng Shih, New Taipei City (TW)

(73) Assignee: COOLER MASTER CO., LTD., New Taipei City (TW)

(21) Appl. No.: 13/854,132

(22) Filed: Mar. 31, 2013

(51) Int. Cl. H05K 7/20

(52) U.S. Cl. CPC H05K 7/20172
USPC 165/121

(57) ABSTRACT

A heat dissipating pad includes a pad body and a fan. The pad body has a hollow accommodating recess and a first fixing structure disposed on a side of the hollow accommodating recess. The fan includes a fan frame. The fan frame is detachably disposed in the hollow accommodating recess and has a second fixing structure. When the fan frame is disposed at a predetermined position in the hollow accommodating recess, the first fixing structure and the second fixing structure are fixed with each other so as to prevent the fan frame from coming off the hollow accommodating recess.

### BACKGROUND OF THE INVENTION

1. Field of the Invention

The invention relates to a heat dissipating pad and, more particularly, to a heat dissipating pad with a detachable fan.

2. Description of the Prior Art

As technology advanced and developed, various electronic devices (e.g. notebook, flat computer, etc.) have been widely used in daily life. Heat dissipation and power consumption are significant issues for the electronic device after being used for a long time. If the heat cannot be dissipated in time, the performance of the electronic device will be affected. Therefore, a user usually places the electronic device on a heat dissipating pad such that a fan of the heat dissipating pad can dissipate heat generated by the electronic device. However, since the fan is usually fixed inside the heat dissipating pad, the user cannot take the fan out of the heat dissipating pad easily for some specific purposes such that the use of the heat dissipating pad is limited.

### SUMMARY OF THE INVENTION

The invention provides a heat dissipating pad with a detachable fan, so as to solve the aforesaid problems.

According to an embodiment of the invention, a heat dissipating pad comprises a pad body and a fan. The pad body has a hollow accommodating recess and a first fixing structure disposed on a side of the hollow accommodating recess. The fan comprises a fan frame. The fan frame is detachably disposed in the hollow accommodating recess and has a second fixing structure. When the fan frame is disposed at a predetermined position in the hollow accommodating recess, the first fixing structure and the second fixing structure are fixed with each other so as to prevent the fan frame from coming off the hollow accommodating recess.

As mentioned in the above, when the fan frame is disposed at the predetermined position in the hollow accommodating recess, a user can place an electronic device on the pad body of the heat dissipating pad such that the fan installed in the heat dissipating pad can dissipate heat from the electronic device actively. Furthermore, the user can detach the fan frame of the fan from the hollow accommodating recess of the pad body and then places the electronic device on the pad body, such that the heat dissipating pad can dissipate heat from the electronic device by wind convection. At this time, the fan can be used to fan the user or other objects. Moreover, after detaching the fan frame of the fan from the hollow accommodating recess of the pad body, the user can also use the pad body of the heat dissipating pad to be a backrest, pillow or the like. Since the fan can be detached from the pad body, the use of the heat dissipating pad of the invention can be increased greatly.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a heat dissipating pad according to a first embodiment of the invention.

FIG. 2 is a perspective view illustrating a front cover shown in FIG. 1 being detached from the fan.

FIG. 3 is a perspective view illustrating the fan shown in FIG. 1 being detached from the pad body.

FIG. 4 is a perspective view illustrating the fan and the pad body shown in FIG. 3 in another viewing angle.

FIG. 5 is a cross-sectional view illustrating the heat dissipating pad shown in FIG. 1 along line X-X.

FIG. 6 is a reference view illustrating a using state of the invention after the fan is detached from the pad body.

FIG. 7 is a perspective view illustrating the fan being hung by a support member.

FIG. 8 is a schematic diagram illustrating a heat dissipating pad according to a second embodiment of the invention.

FIG. 9 is a schematic diagram illustrating a heat dissipating pad according to a third embodiment of the invention.

FIG. 10 is a schematic diagram illustrating a heat dissipating pad according to a fourth embodiment of the invention.

FIG. 11 is a schematic diagram illustrating a heat dissipating pad according to a fifth embodiment of the invention.

FIG. 12 is a schematic diagram illustrating a heat dissipating pad according to a sixth embodiment of the invention.

FIG. 13 is a schematic diagram illustrating a heat dissipating pad according to a seventh embodiment of the invention.

FIG. 14 is a schematic diagram illustrating a heat dissipating pad according to an eighth embodiment of the invention.

FIG. 15 is a schematic diagram illustrating the pad body shown in FIG. 14 being folded to be a pillow.

### DETAILED DESCRIPTION

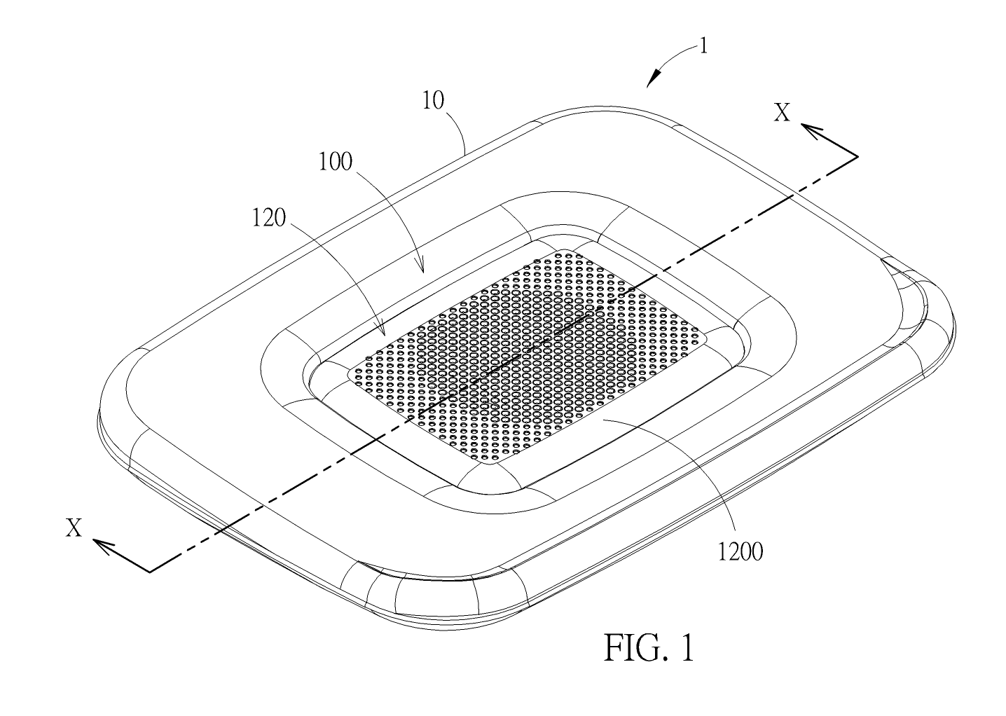

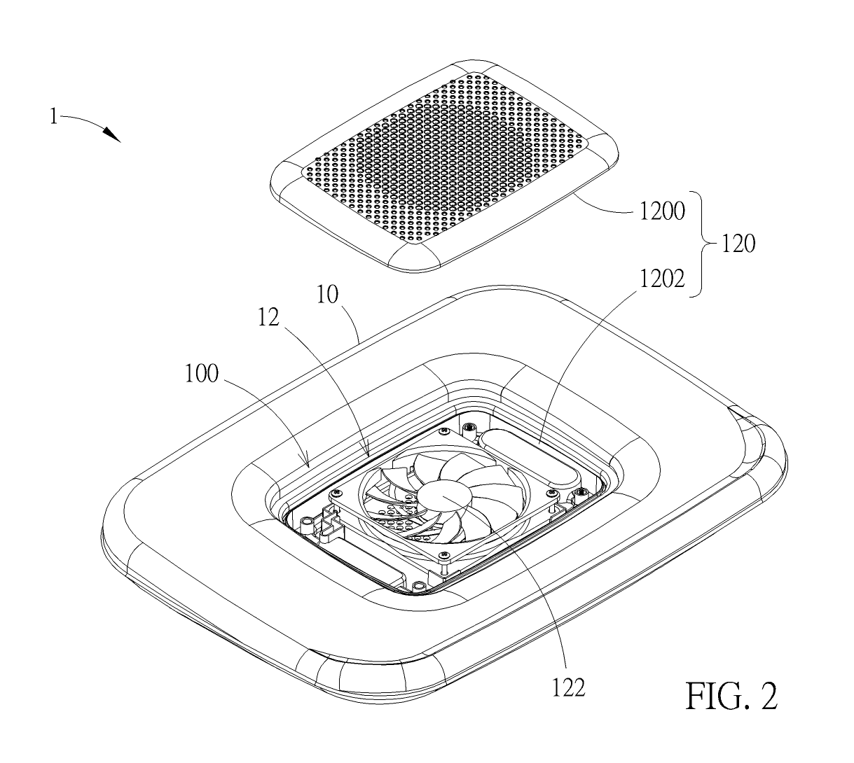

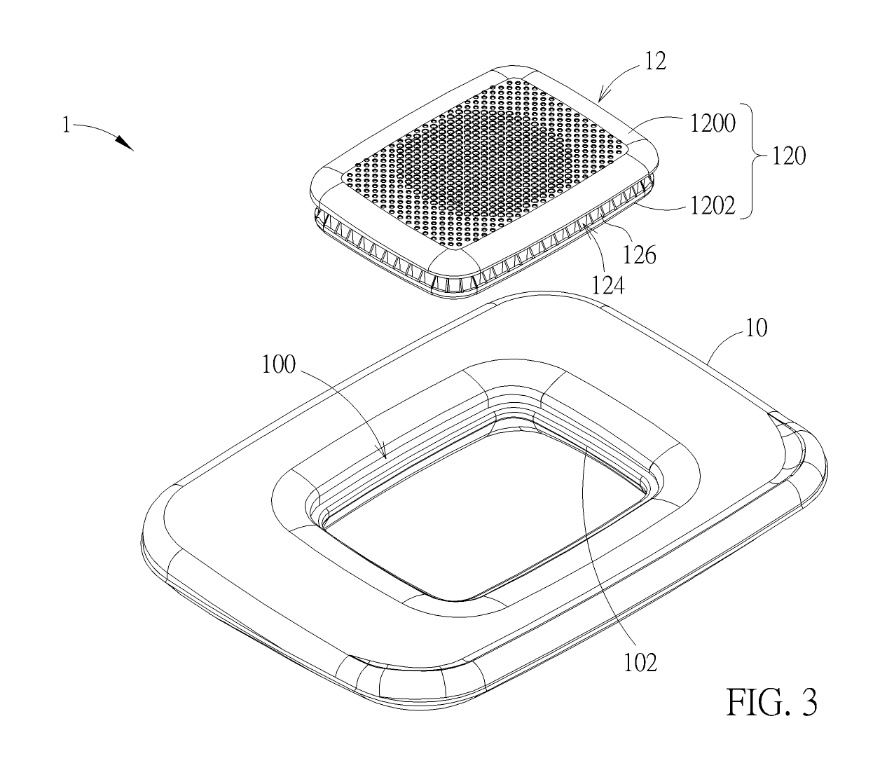

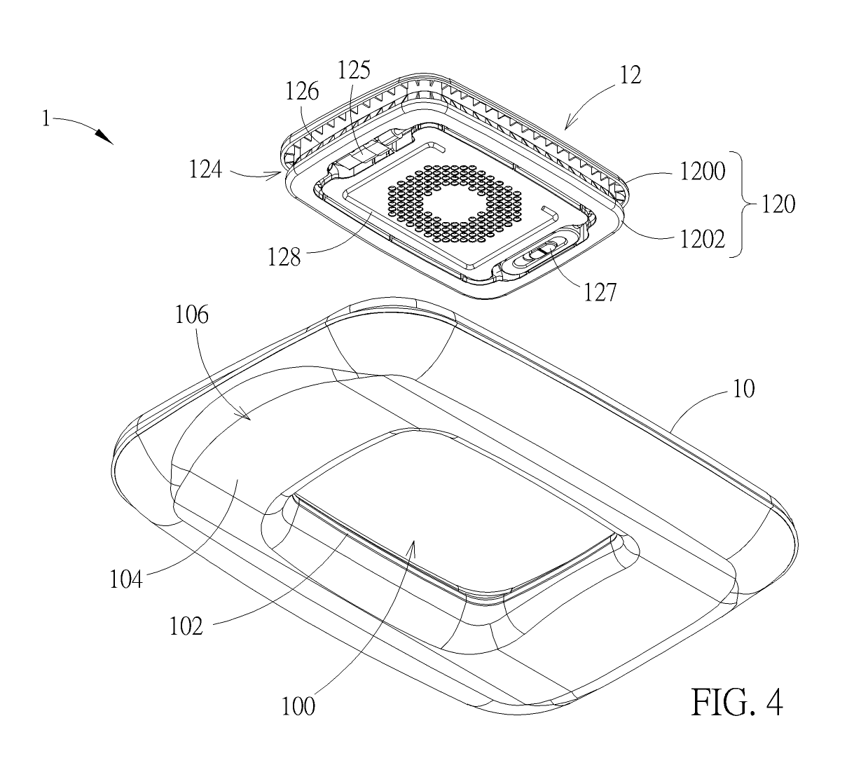

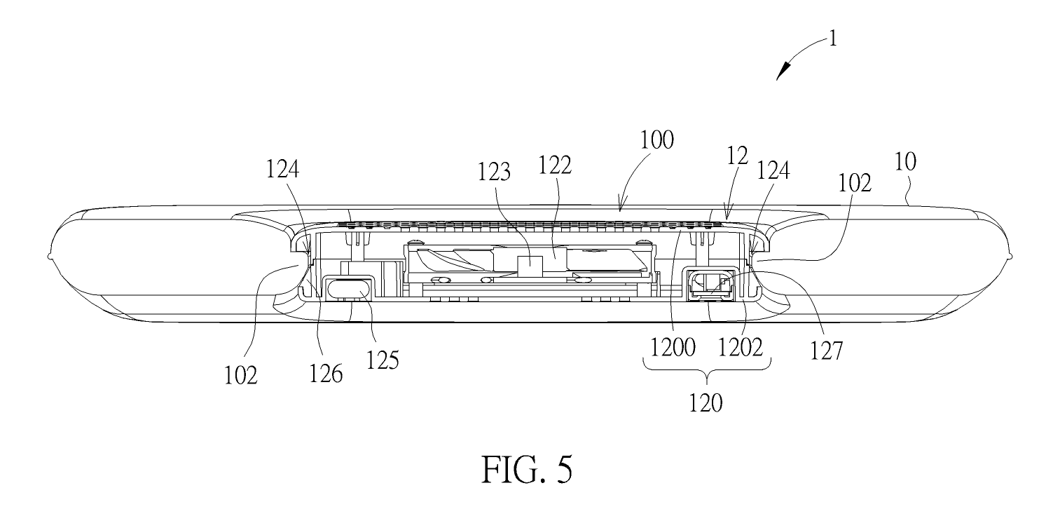

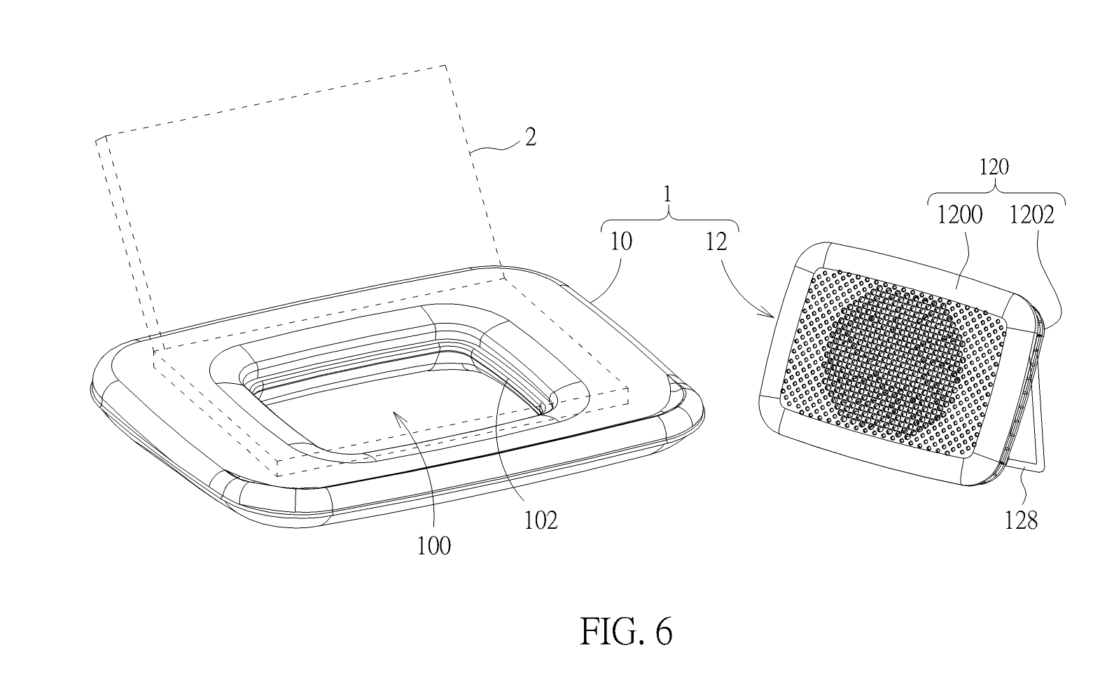

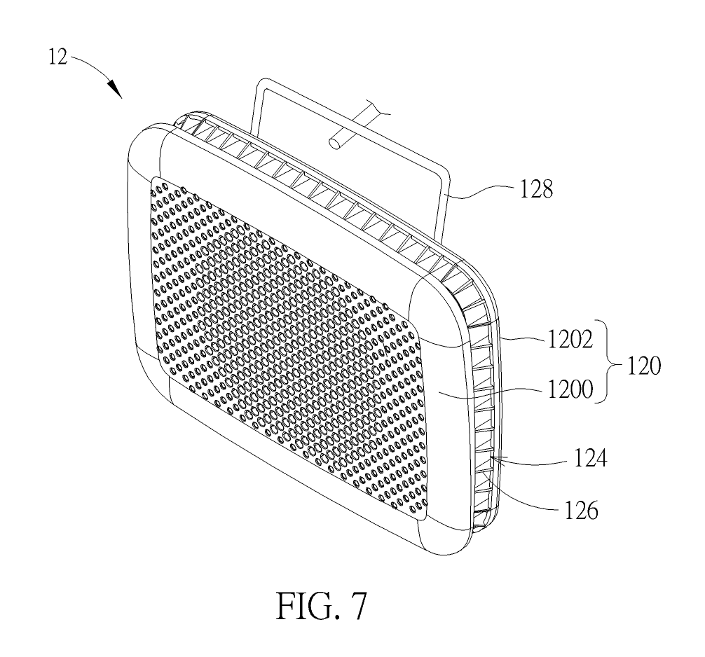

Referring to FIGS. 1 to 7, FIG. 1 is a perspective view illustrating a heat dissipating pad 1 according to a first embodiment of the invention, FIG. 2 is a perspective view illustrating a front cover 1200 shown in FIG. 1 being detached from the fan 12, FIG. 3 is a perspective view illustrating the fan 12 shown in FIG. 1 being detached from the pad body 10, FIG. 4 is a perspective view illustrating the fan 12 and the pad body 10 shown in FIG. 3 in another viewing angle, FIG. 5 is a cross-sectional view illustrating the heat dissipating pad 1 shown in FIG. 1 along line X-X, FIG. 6 is a reference view illustrating a using state of the invention after the fan 12 is detached from the pad body 10, and FIG. 7 is a perspective view illustrating the fan 12 being hung by a support member 128.

As shown in FIGS. 1 to 5, the heat dissipating pad 1 comprises a pad body 10 and a fan 12. The pad body 10 has a hollow accommodating recess 100 and a first fixing structure 102 disposed on a side of the hollow accommodating recess 100. The fan 12 comprises a fan frame 120, a fan wheel 122 and a driving device 123, wherein the fan frame 120 comprises a front cover 1200 and a back cover 1202, and there are lots of air holes formed on the front cover 1200 and the back cover 1202. The fan wheel 122 and the driving device 123 are disposed in the fan frame 120. The fan frame 120 is detachably disposed in the hollow accommodating recess 100 of the pad body 10 and has a second fixing structure 124. When the fan frame 120 is disposed at a predetermined position in the hollow accommodating recess 100 of the pad body 10, the first fixing structure 102 and the second fixing structure 124 can be fixed with each other so as to prevent the fan frame 120 from coming off the hollow accommodating recess 100. In practical applications, the driving device 123 may be, but not limited to, a motor. The driving device 123 is connected to the fan wheel 122 and used for driving the fan wheel 122 to rotate. Furthermore, the driving device 123 may be further connected to a USB cable 125 and receiving power from the USB cable 123. Needless to say, the invention may utilize a battery or other power supply device to provide power for the driving device 123 according to practical applications. Moreover, the driving device 123 may be connected to a control circuit 127 and controlled by the control circuit 127 to adjust rotating speed, rotating direction (clockwise or counterclockwise) and so on of the fan 12. Accordingly, when the fan wheel 122 rotates, the air will be blown into the air holes of the back cover 1202 and out of the air holes of the front cover 1200. It should be noted that the fan wheel 122 may rotates to blow the air into the air holes of the front cover 1200 and out of the air holes of the back cover 1202 according to practical applications.

As shown in FIG. 5, the first fixing structure 102 protrudes toward an inside of the hollow accommodating recess 100 and the second fixing structure 124 is a recess. In this embodiment, a thickness of the first fixing structure 102 varies gradiently and the second fixing structure 124 comprises a plurality of rib portions 126 arranged separately. To match the shape of the first fixing structure 102, the rib portions 126 are, but not limited to, triangular. In this embodiment, the pad body 10 may be made of sponge, rubber or other flexible materials, such that the first fixing structure 102 can deform elastically due to compression. To assemble the pad body 10 with the fan 12, the fan frame 120 of the fan 12 can be pressed into the hollow accommodating recess 100 of the pad body 10. At this time, the first fixing structure 102 will deform elastically due to compression. After the fan frame 120 is pressed into the hollow accommodating recess 100, the first fixing structure 102 will recover and be engaged in the second fixing structure 124, such that the first fixing structure 102 and the second fixing structure 124 are fixed with each other so as to prevent the fan frame 120 from coming off the hollow accommodating recess 100. When the fan frame 120 is disposed at a predetermined position in the hollow accommodating recess 10, a user can place an electronic device (not shown) on the pad body 10 of the heat dissipating pad 1 such that the fan 12 installed in the heat dissipating pad 1 can dissipate heat from the electronic device actively.

On the other hand, the user can push the fan frame 120 of the fan 12 out of the hollow accommodating recess 100 of the pad body 10 so as to detach the fan 12 from the pad body 10. At this time, the first fixing structure 102 will deform elastically due to compression and then come off the second fixing structure 124. After the fan frame 120 comes off the hollow accommodating recess 100, the first fixing structure 102 will recover accordingly.

As shown in FIG. 4, the fan 12 further comprises a support member 128 connected to the back cover 1202 of the fan 120 . In this embodiment, the support member 128 is pivotally connected to the back cover 1202 of the fan frame 120. However, in another embodiment, the support member 128 may be also connected to a specific position of the fan frame 120 in other manners according to practical applications. As shown in FIG. 6, after detaching the fan 12 from the pad body 10, the user can place an electronic device 2 (represented by dot lines) on the pad body 10 to perform operation and rotate the support member 128 with respect to the fan frame 120, so as to support the fan 12 on a plane by the support member 128 and use the fan 12 to fan the user. As shown in FIG. 4, a bottom 104 of the pad body 10 is arc-shaped and a blowhole 106 is formed on the bottom 104 and communicates with the hollow accommodating recess 100. Accordingly, when the user detaches the fan 12 from the pad body 10 and places the electronic device 2 on the pad body 10, a wind convection channel will be formed within the blowhole 106 and the hollow accommodating recess 100, so as to dissipate heat from the electronic device 2 by wind convection. Furthermore, besides using the support member 128 to support the fan 12 on the plane, the support member 128 may be also used to hang the fan 12, as shown in FIG. 7. Moreover, after detaching the fan frame 120 of the fan 12 from the hollow accommodating recess 100 of the pad body 10, the user can also use the pad body 10 to be a backrest, pillow or the like since the pad body 10 is made of sponge, rubber or other flexible materials.

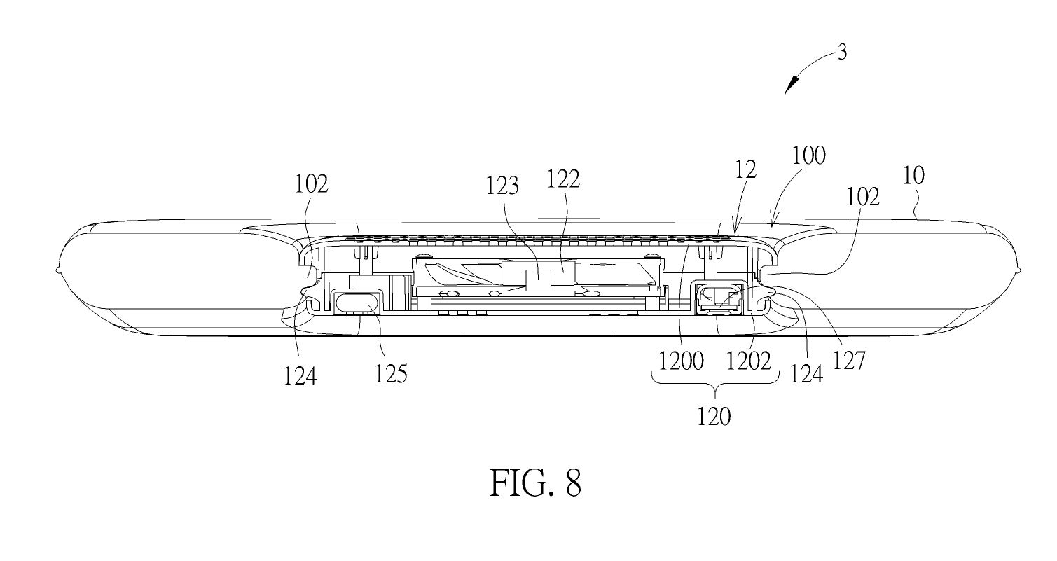

Referring to FIG. 8 along with FIG. 5, FIG. 8 is a schematic diagram illustrating a heat dissipating pad 3 according to a second embodiment of the invention. The difference between the heat dissipating pad 3 and the aforesaid heat dissipating pad 1 is that the second fixing structure 124 of the heat dissipating pad 3 is a protrusion. Since the pad body 10 may be made of sponge, rubber or other flexible materials, the second fixing structure 124 will sink into the first fixing structure 102 after the fan frame 120 is pressed into the hollow accommodating recess 100, such that the first fixing structure 102 and the second fixing structure 124 are fixed with each other so as to prevent the fan frame 120 from coming off the hollow accommodating recess 100.

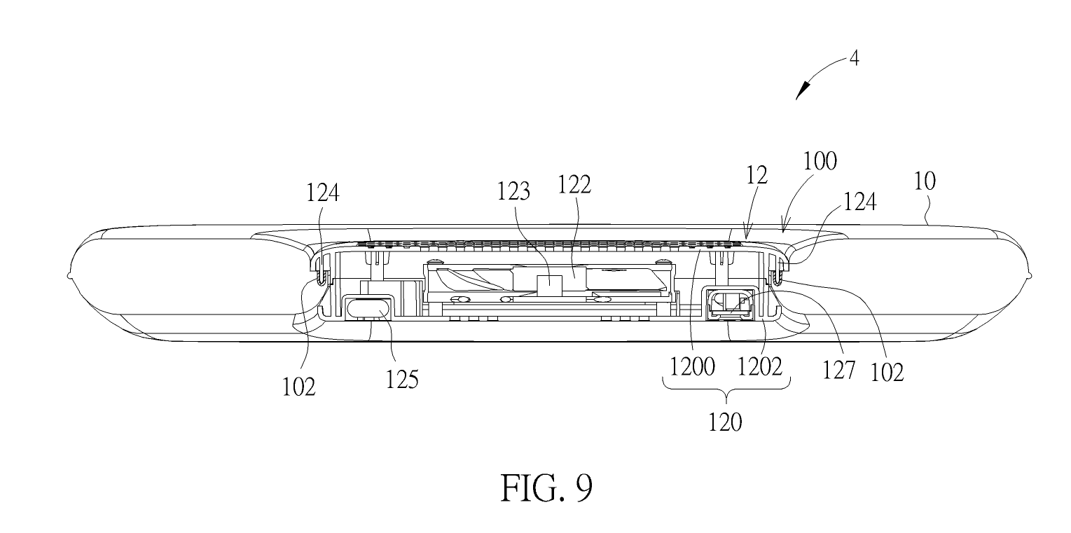

Referring to FIG. 9 along with FIG. 5, FIG. 9 is a schematic diagram illustrating a heat dissipating pad 4 according to a third embodiment of the invention. The difference between the heat dissipating pad 4 and the aforesaid heat dissipating pad 1 is that the first fixing structure 102 of the heat dissipating pad 4 is a U-shaped recess made of rubber and the second fixing structure 124 is a pillar corresponding to the U-shaped recess. After the fan frame 120 is pressed into the hollow accommodating recess 100, the second fixing structure 124 is engaged in the first fixing structure 102, such that the first fixing structure 102 and the second fixing structure 124 are fixed with each other so as to prevent the fan frame 120 from coming off the hollow accommodating recess 100.

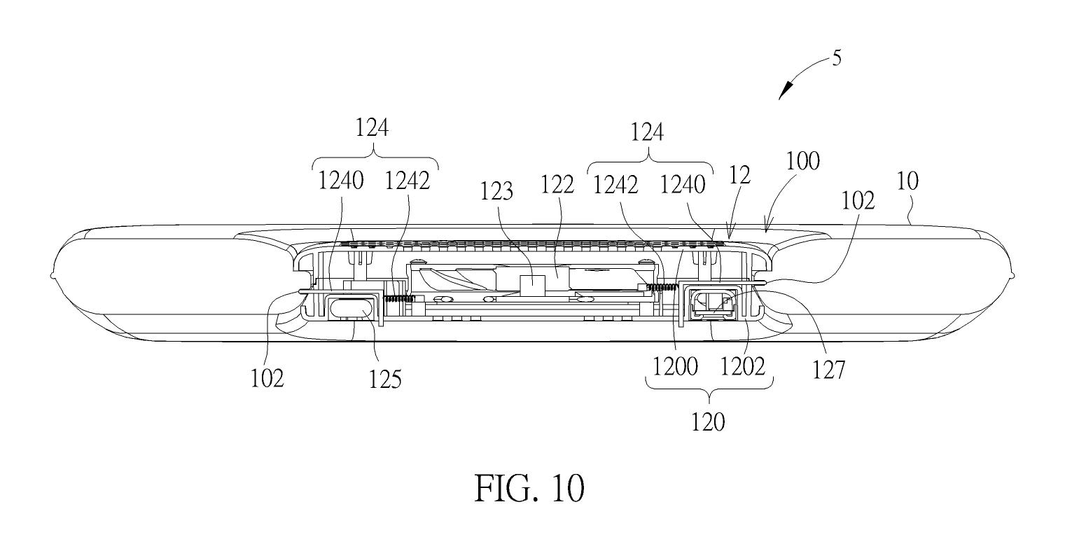

Referring to FIG. 10 along with FIG. 5, FIG. 10 is a schematic diagram illustrating a heat dissipating pad 5 according to a fourth embodiment of the invention. The difference between the heat dissipating pad 5 and the aforesaid heat dissipating pad 1 is that the first fixing structure 102 of the heat dissipating pad 5 is a recess and the second fixing structure 124 comprises an engaging member 1240 and a resilient member 1242, wherein the engaging member 1240 is movably disposed in the fan frame 120 and opposite ends of the resilient member 1242 are fixed on the engaging member 1240 and the fan frame 120. In this embodiment, the resilient member 1242 may be a spring. Furthermore, the pad body 10 may be made of plastic except sponge, rubber or other flexible materials. As shown in FIG. 10, the user can push the engaging member 1240 toward the fan wheel 122 to compress the resilient member 1242 and then place the fan frame 120 into the hollow accommodating recess 100. When the fan frame 120 is disposed at the predetermined position in the hollow accommodating access 100, the user can release the engaging member 1240 such that the resilient member 1242 generates an elastic recovery force to push the engaging member 1240 away from the fan wheel 122. Consequently, an end of the engaging member 1240 is engaged in the first fixing structure 102 (i.e. recess). Accordingly, the first fixing structure 102 and the second fixing structure 124 are fixed with each other so as to prevent the fan frame 120 from coming off the hollow accommodating recess 100.

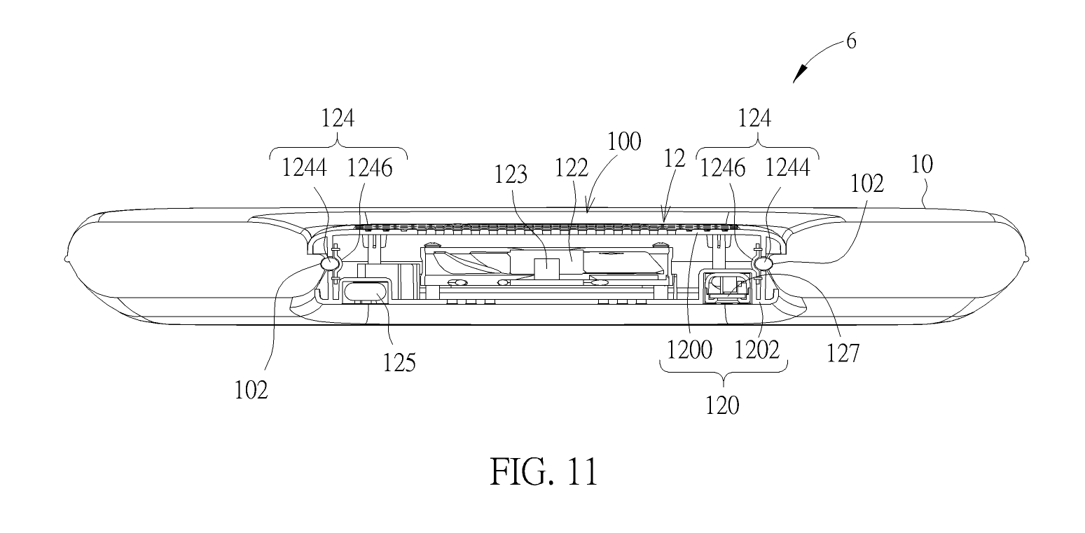

Referring to FIG. 11 along with FIG. 5, FIG. 11 is a schematic diagram illustrating a heat dissipating pad 6 according to a fifth embodiment of the invention. The difference between the heat dissipating pad 6 and the aforesaid heat dissipating pad 1 is that the first fixing structure 102 of the heat dissipating pad 6 is a recess and the second fixing structure 124 comprises a ball 1244 and a resilient plate 1246, wherein the resilient plate 1246 fixes the ball 1244 in the fan frame 120 and the ball 1244 is exposed out of the fan frame 120. In this embodiment, the ball 1244 and the resilient plate 1246 may be made of, but not limited to, metal (e.g. aluminum, copper, etc.). Furthermore, the pad body 10 may be made of plastic except sponge, rubber or other flexible materials. As shown in FIG. 11, when the fan frame 120 is placed into the hollow accommodating recess 100, the ball 1244 will move toward the fan wheel 122 due to compression such that the resilient plate 1246 expands outwardly. When the fan frame 120 is disposed at the predetermined position in the hollow accommodating access 100, the resilient plate 1246 generates an elastic recovery force to push the ball 1244 away from the fan wheel 122 such that the ball 1244 is engaged in the first fixing structure 102 (i.e. recess). Accordingly, the first fixing structure 102 and the second fixing structure 124 are fixed with each other so as to prevent the fan frame 120 from coming off the hollow accommodating recess 100.

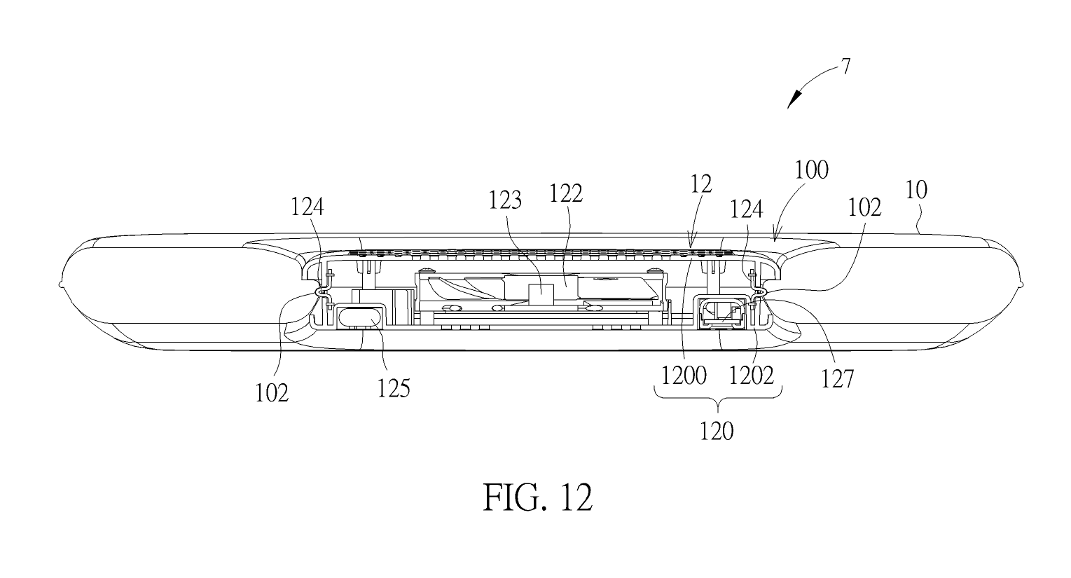

Referring to FIG. 12 along with FIG. 5, FIG. 12 is a schematic diagram illustrating a heat dissipating pad 7 according to a sixth embodiment of the invention. The difference between the heat dissipating pad 7 and the aforesaid heat dissipating pad 1 is that the first fixing structure 102 of the heat dissipating pad 7 is a recess and the second fixing structure 124 is an Q-shaped resilient plate, wherein the Q-shaped resilient plate is fixed in the fan frame 120 and an end of the Q-shaped resilient plate is exposed out of the fan frame 120. In this embodiment, the Q-shaped resilient plate may be made of, but not limited to, metal (e.g. aluminum, copper, etc.). Furthermore, the pad body 10 may be made of plastic except sponge, rubber or other flexible materials. As shown in FIG. 12, when the fan frame 120 is placed into the hollow accommodating recess 100, the exposed end of the Q-shaped resilient plate will move toward the fan wheel 122 due to compression. When the fan frame 120 is disposed at the predetermined position in the hollow accommodating access 100, the exposed end of the Q-shaped resilient plate is engaged in the first fixing structure (i.e. recess). Accordingly, the first fixing structure 102 and the second fixing structure 124 are fixed with each other so as to prevent the fan frame 120 from coming off the hollow accommodating recess 100.

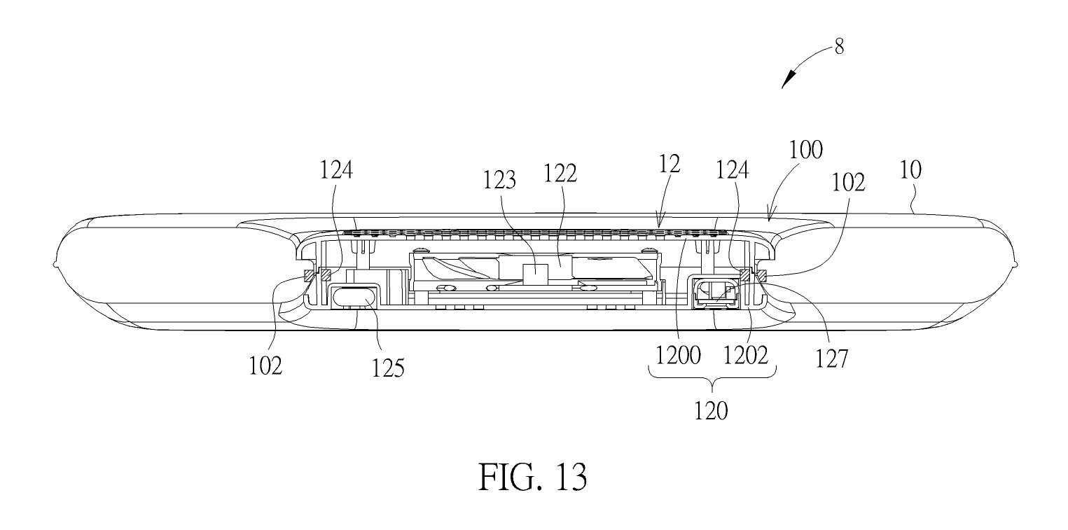

Referring to FIG. 13 along with FIG. 5, FIG. 13 is a schematic diagram illustrating a heat dissipating pad 8 according to a seventh embodiment of the invention. The difference between the heat dissipating pad 8 and the aforesaid heat dissipating pad 1 is that one of the first fixing structure 102 and the second fixing structure 124 of the heat dissipating pad 8 is a magnet, and another one of the first fixing structure 102 and the second fixing structure 124 is a magnet or a magnetic induction material (e.g. metal including copper, iron, silver, etc.). In other words, when the first fixing structure 102 and the second fixing structure 124 are close to each other, a magnetic attraction force will be generated between the first fixing structure 102 and the second fixing structure 124. Accordingly, when the fan frame 120 is disposed at the predetermined position in the hollow accommodating access 100, the first fixing structure 102 and the second fixing structure 124 will be fixed with each other due to the magnetic attraction force so as to prevent the fan frame 120 from coming off the hollow accommodating recess 100. The user can push or press the fan frame 120 with an external force larger than the magnetic attraction force, so as to detach the fan 12 from the pad body 10.

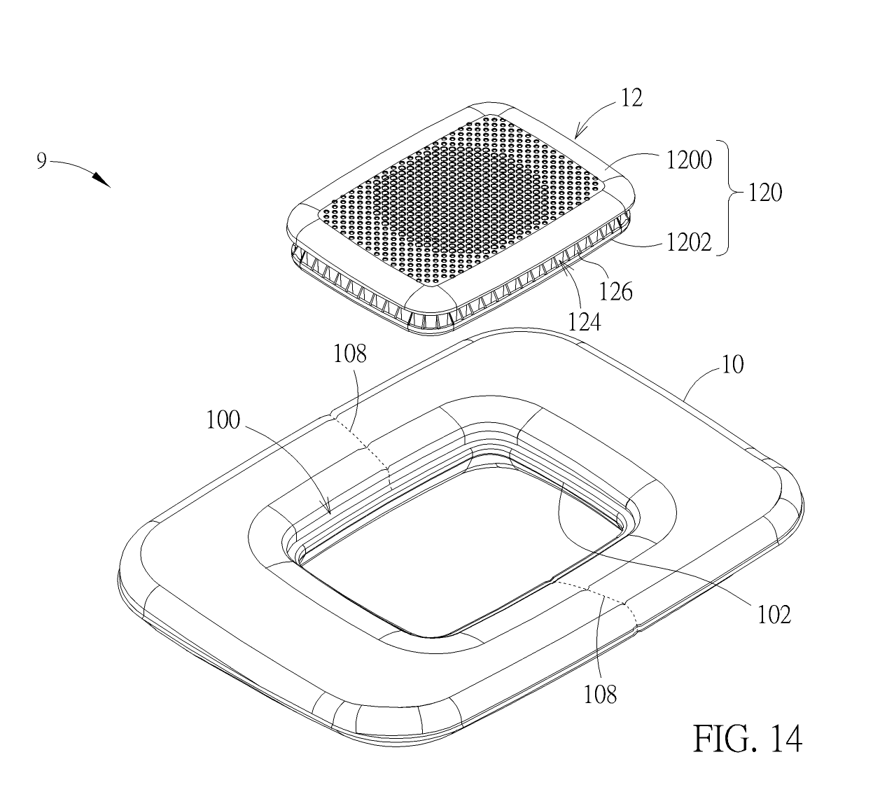

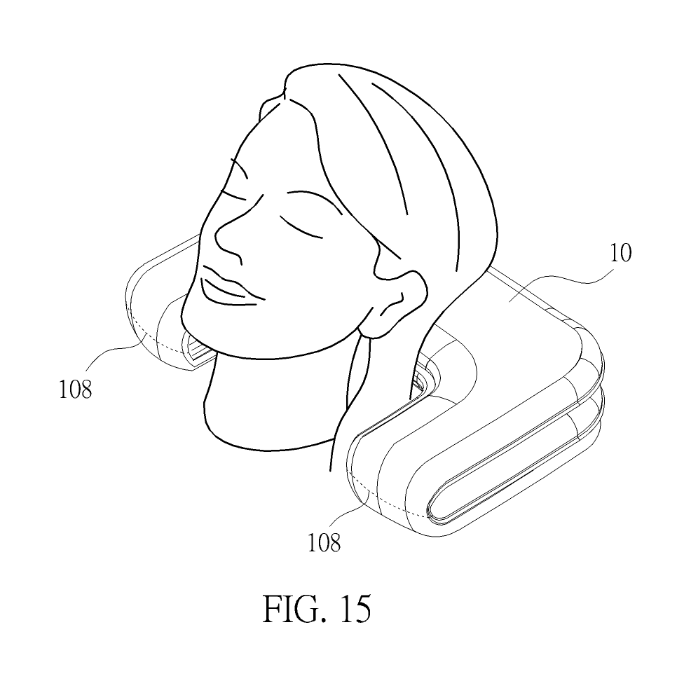

Referring to FIGS. 14 and 15 along with FIG. 3, FIG. 14 is a schematic diagram illustrating a heat dissipating pad 9 according to an eighth embodiment of the invention, and FIG. 15 is a schematic diagram illustrating the pad body 10 shown in FIG. 14 being folded to be a pillow. The difference between the heat dissipating pad 9 and the aforesaid heat dissipating pad 1 is that the pad body 10 of the heat dissipating pad 9 further comprises a folding line 108 for folding the pad body 10, as shown in FIG. 14. In this embodiment, the pad body 10 may be made of sponge, rubber or other flexible materials. Accordingly, after detaching the fan frame 120 of the fan 12 from the hollow accommodating recess 100 of the pad body 10, the user can fold the pad body 10 along the folding line 108 and then use the folded pad body 10 to be a pillow, as shown in FIG. 15.

As mentioned in the above, when the fan frame is disposed at the predetermined position in the hollow accommodating recess, a user can place an electronic device on the pad body of the heat dissipating pad such that the fan installed in the heat dissipating pad can dissipate heat from the electronic device actively. Furthermore, the user can detach the fan frame of the fan from the hollow accommodating recess of the pad body and then places the electronic device on the pad body, such that the heat dissipating pad can dissipate heat from the electronic device by wind convection. At this time, the fan can be used to fan the user or other objects . Moreover, after detaching the fan frame of the fan from the hollow accommodating recess of the pad body, the user can also use the pad body of the heat dissipating pad to be a backrest, pillow or the like. Since the fan can be detached from the pad body, the use of the heat dissipating pad of the invention can be increased greatly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A heat dissipating pad comprising:
a pad body having a hollow accommodating recess and a first fixing structure disposed on a side of the hollow accommodating recess; and
a fan comprising a fan frame, the fan frame being detachably disposed in the hollow accommodating recess and having a second fixing structure, when the fan frame is disposed at a predetermined position in the hollow accommodating recess, the first fixing structure and the second fixing structure being fixed with each other so as to prevent the fan frame from coming off the hollow accommodating recess.

2. The heat dissipating pad of claim 1, wherein the pad body is made of sponge, rubber or plastic.

3. The heat dissipating pad of claim 1, wherein the first fixing structure protrudes toward an inside of the hollow accommodating recess and the second fixing structure is a recess or a protrusion.

4. The heat dissipating pad of claim 1, wherein a thickness of the first fixing structure varies gradiently.

5. The heat dissipating pad of claim 1, wherein the first fixing structure is a U-shaped recess made of rubber and the second fixing structure is a pillar corresponding to the U-shaped recess.

6. The heat dissipating pad of claim 1, wherein the first fixing structure is a recess, the second fixing structure comprises an engaging member and a resilient member, the engaging member is movably disposed in the fan frame, opposite ends of the resilient member are fixed on the engaging member and the fan frame, when the fan frame is disposed at the predetermined position in the hollow accommodating access, an end of the engaging member is engaged in the recess.

7. The heat dissipating pad of claim 1, wherein the first fixing structure is a recess, the second fixing structure comprises a ball and a resilient plate, the resilient plate fixes the ball in the fan frame, the ball is exposed out of the fan frame, when the fan frame is disposed at the predetermined position in the hollow accommodating access, the ball is engaged in the recess.

8. The heat dissipating pad of claim 1, wherein the first fixing structure is a recess, the second fixing structure is an Q-shaped resilient plate, the Q-shaped resilient plate is fixed in the fan frame, an end of the Q-shaped resilient plate is exposed out of the fan frame, when the fan frame is disposed at the predetermined position in the hollow accommodating access, the exposed end of the Q-shaped resilient plate is engaged in the recess.

9. The heat dissipating pad of claim 1, wherein one of the first fixing structure and the second fixing structure is a magnet, and another one of the first fixing structure and the second fixing structure is a magnet or a magnetic induction material.

10. The heat dissipating pad of claim 1, wherein the fan further comprises a support member connected to the fan frame.

11. The heat dissipating pad of claim 1, wherein a blowhole is formed on a bottom of the pad body and communicates with the hollow accommodating recess.

12. The heat dissipating pad of claim 1, wherein the pad body further comprises a folding line for folding the pad body.

13. The heat dissipating pad of claim 1, wherein the fan further comprises a fan wheel and a driving device, the fan wheel and the driving device are disposed in the fan frame, and the driving device is connected to the fan wheel and used for driving the fan wheel to rotate.

14. The heat dissipating pad of claim 13, wherein the driving device is further connected to a USB cable.

15. The heat dissipating pad of claim 13, wherein the driving device is further connected to a control circuit.
